(19) United States
(12) Patent Application Publication
(10) Pub. No.: US 2017/0077368 A1
(43) Pub. Date: Mar. 16, 2017

(54) LIGHT-EMITTING DEVICE

(71) Applicant: Panasonic Intellectual Property Management Co., Ltd., Osaka (JP)

(72) Inventors: Hisaki FUJITANI, Kyoto (JP); Kenji SUGIURA, Osaka (JP); Naoki TAGAMI, Miyagi (JP); Kosuke TAKEHARA, Osaka (JP)

(21) Appl. No.: 15/258,548

(22) Filed: Sep. 7, 2016

(30) Foreign Application Priority Data
Sep. 10, 2015 (JP) 2015-178938

(51) Int. Cl. H01L 33/62; H01L 27/15; H01L 33/48; H01L 33/54

(52) U.S. Cl. CPC H01L 33/62; H01L 33/54; H01L 27/15; H01L 33/483

(57) ABSTRACT

A light-emitting device includes: a board which is a resin board having an elongated shape; a conductive film formed on the board; and a plurality of LED elements disposed over the board. The plurality of LED elements include two adjacent LED elements arranged along a first direction. The conductive film includes (i) a first conductive part which electrically connects the two adjacent LED elements and at least a portion of which is located between the two adjacent LED elements and (ii) a second conductive part located on two outer sides of the first conductive part in a second direction intersecting the first direction. The second conductive part has a slit on each of the two outer sides of the first conductive part, and the slit extends in the second direction intersecting the longitudinal direction of the board.

### CROSS REFERENCE TO RELATED APPLICATION

This application claims the benefit of priority of Japanese Patent Application Number 2015-178938 filed on Sep. 10, 2015, the entire content of which is hereby incorporated by reference.

### BACKGROUND

1. Technical Field

The present disclosure relates to a light-emitting device including light-emitting elements such as light-emitting diodes (LEDs).

2. Description of the Related Art

Due to their high efficiency and long life span, semiconductor light-emitting elements such as LEDs are widely used as light sources in various apparatuses. For example, LEDs are used as illumination light sources in illumination apparatuses and backlight sources in liquid crystal display apparatuses.

LEDs are generally unitized as an LED module (light-emitting device) to be built into various apparatuses. For example, the LED module includes a board, one or more LED elements mounted on the board, and lines (conductive film) patterned on the board.

More specifically, chip on board (COB) LED modules in which one or a plurality of LED chips (LED elements) are mounted directly on the board are known (Japanese Unexamined Patent Application Publication No. 2011-176017).

Also known are surface mount device (SMD) LED modules in which one or a plurality of SMD LED elements packaged by housing an LEI) chip in a container are mounted on the board.

### SUMMARY

LED modules having an elongated shape are used in some cases for apparatuses such as liquid crystal display apparatuses or illumination apparatuses, e.g. straight tube LED lamps or base lights. In these cases, a board which also has an elongated shape is used as the board for mounting the LED elements.

Using a board having an elongated shape, however, causes the board to warp. Using a resin board which is based on a resin material particularly causes the board to warp.

Warping of the board places a load on portions connecting LED elements and the patterned lines (conductive film), thus causing a problem of faulty electrical continuity (no illumination). For example, COB LED modules have LED chips and the patterned lines connected by bonding wires. When the board warps, strain stress caused by the warping of the board places a load on portions connecting the bonding wires and the patterned lines, which may result in faulty electrical continuity caused by wire breakage.

The present disclosure has been conceived in order to solve such a problem, and it is an object of the present disclosure to provide a light-emitting device capable of reducing the occurrence of faulty electrical continuity caused by wire breakage attributable to warping of a board.

In order to achieve the above object, a light-emitting device according to an aspect of the present disclosure is a light-emitting device including: a board which is a resin board having an elongated shape; a conductive film formed on the board; and a plurality of light-emitting elements disposed over the board, wherein the plurality of light-emitting elements include two adjacent light-emitting elements arranged along a first direction, the conductive film includes (i) a first conductive part which electrically connects the two adjacent light-emitting elements and at least a portion of which is located between the two adjacent light-emitting elements and (ii) a second conductive part located on two outer sides of the first conductive part in a second direction intersecting the first direction, and the second conductive part has a slit on each of the two outer sides of the first conductive part, the slit extending in the second direction intersecting a longitudinal direction of the board.

According to the present disclosure, it is possible to reduce the occurrence of faulty electrical continuity caused by wire breakage attributable to warping of a board.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a perspective view of a light-emitting device according to an embodiment;

FIG. 2 is a plan view of a light-emitting device according to an embodiment;

FIG. 3A is an enlarged plan view of an important part of a light-emitting device according to an embodiment (an enlarged view of region A surrounded by dashed lines in FIG. 2) (a resist film is not illustrated);

FIG. 3B is an enlarged plan view of an important part of a light-emitting device according to an embodiment (an enlarged view of region A surrounded by dashed lines in FIG. 2) (a resist film and a sealing member are not illustrated);

FIG. 4A is a cross-sectional view of a light-emitting device according to an embodiment along IVA-IVA line in FIG. 3B;

FIG. 4B is a cross-sectional view of a light-emitting device according to an embodiment along IVB-IVB line in FIG. 3B;

FIG. 5 is an enlarged plan view of a longitudinal end portion of a light-emitting device according to an embodiment;

FIG. 6 is an enlarged plan view of a light-emitting device of a comparative example;

FIG. 7 is a cross-sectional view of a warped light-emitting device;

FIG. 8 is an enlarged plan view of an important part of a light-emitting device according to Variation 1;

FIG. 9 is an enlarged plan view of an important part of a light-emitting device according to Variation 2;

FIG. 10 is an enlarged plan view of an important part of a light-emitting device according to Variation 3; and

FIG. 11 is an enlarged plan view of an important part of a light-emitting device according to Variation 4.

### DETAILED DESCRIPTION OF THE EMBODIMENT

Hereinafter, an embodiment of the present disclosure will be described. It is to be noted that the embodiment described below is to show a preferable specific example of the present disclosure. Therefore, the numerical values, structural elements, the arrangement and connection of the structural elements, steps, the processing order of the steps etc., shown in the following embodiment are mere examples, and are therefore not intended to limit the present disclosure. Thus, among the structural elements in the following embodiment, structural elements not recited in any one of the independent claims representing the most generic concepts of the present disclosure are described as arbitrary structural elements.

It is to be noted that each drawing is a schematic diagram and is not necessarily a precise illustration. Furthermore, in the drawings, the same reference numerals refer to substantially the same elements, and overlapping description is omitted or simplified. In the Specification and Drawings, the X axis, Y axis, and Z axis represent the three axes of the three-dimensional orthogonal coordinate system, and the X-axis direction is assumed to be the longitudinal direction of board 10.

### EMBODIMENT

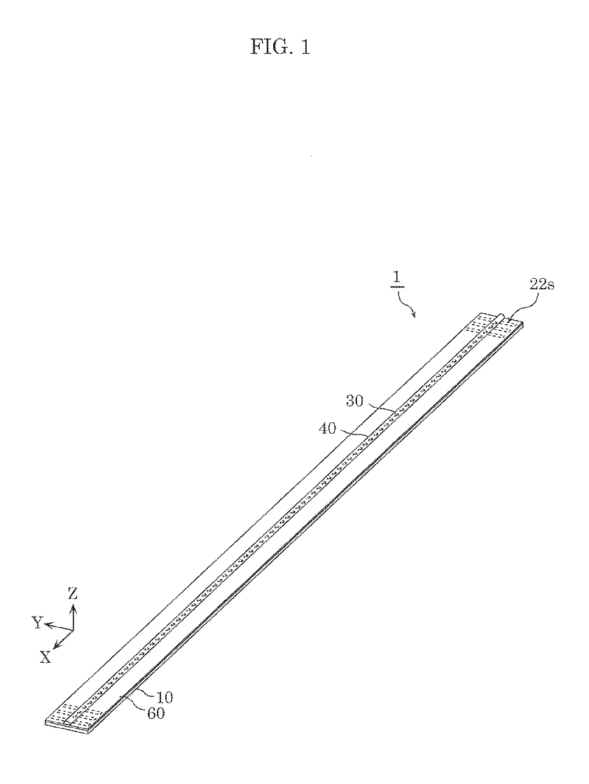

A structure of light-emitting device 1 according to an embodiment will be described using FIG. 1 to FIG. 4B.

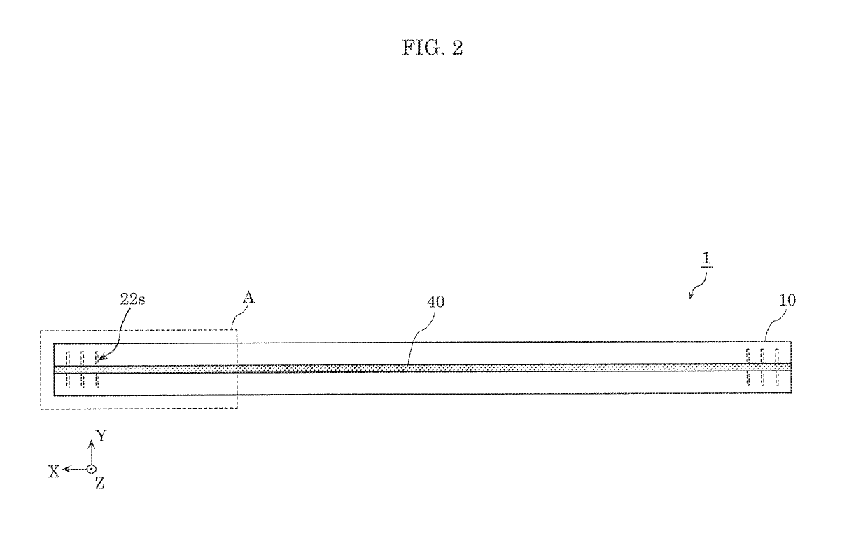

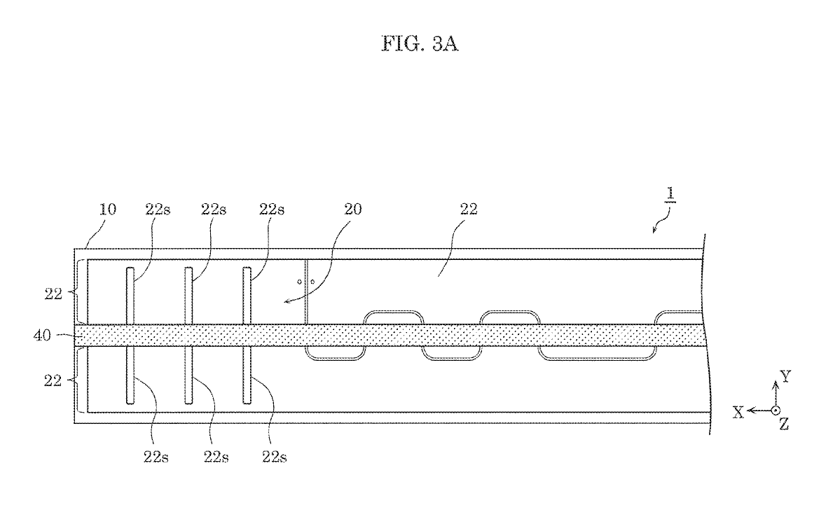

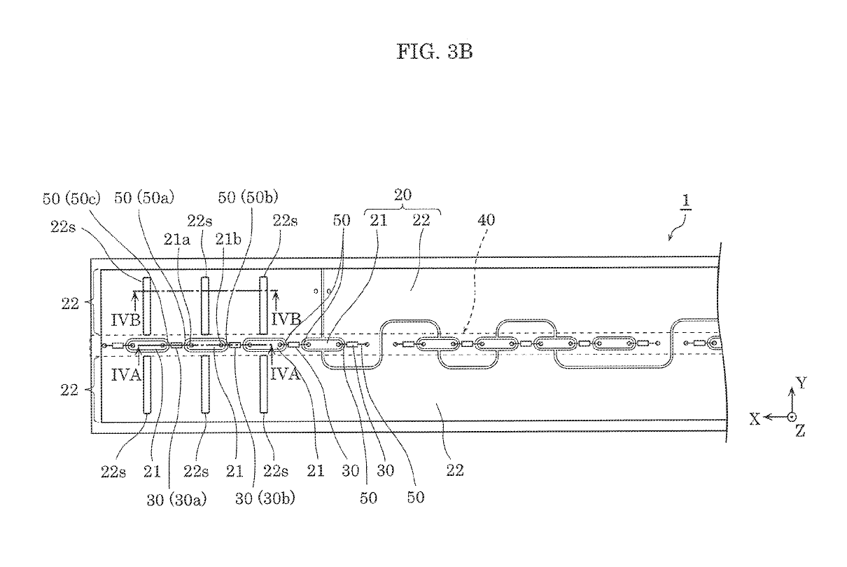

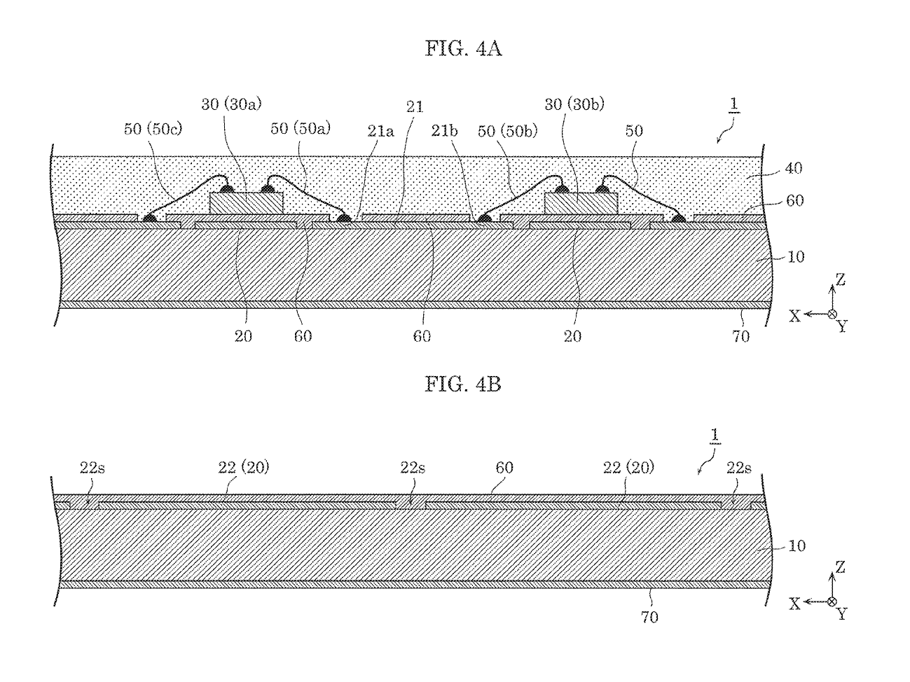

FIG. 1 is a perspective view of light-emitting device 1 according to an embodiment. FIG. 2 is a plan view of light-emitting device 1. FIG. 3A and FIG. 3B are enlarged views of region A surrounded by dashed lines in FIG. 2. In FIG. 3A, resist film 60 is omitted, whereas in FIG. 3B, resist film 60 and sealing member 40 are omitted. It is to be noted that in FIG. 3B, the position of sealing member 40 is indicated by dashed lines. FIG. 4A is a cross-sectional view of light-emitting device 1 along IVA-IVA line in FIG. 3B, and FIG. 4B is a cross-sectional view of light-emitting device 1 along IVB-IVB line in FIG. 3B.

As illustrated in FIG. 1 to FIG. 4B, light-emitting device 1 includes board 10, conductive film 20 formed on board 10, and a plurality of LED elements 30 disposed over board 10. In the present embodiment, light-emitting device 1 further includes sealing member 40, wires 50, and resist film 60.

Light-emitting device 1 according to the present embodiment is a COB LED module in which LED chips are mounted directly on board 10 as LED elements 30, and emits white light, for example. Hereinafter, each structural member of light-emitting device 1 will be described in detail.

### [Board]

Board 10 is a resin board which is based on a resin. For example, a glass epoxy board (FR-4) including glass epoxy containing glass fiber and an epoxy resin, a glass composite board (CEM-3), a paper phenol board (FR-1, FR-2) including a phenol resin and kraft paper for example, a paper epoxy board (FR-3) including paper and an epoxy resin, or a flexible board including, for example, polyimide is used for the resin board (board 10).

Board 10 has an elongated shape. Board 10 is, for example, a rectangular board elongated in the X-axis direction. It is to be noted that board 10 is not limited to being rectangular as long as board 10 has an elongated shape.

Board 10 is a mounting board for mounting LED elements 30. Thus, as illustrated in FIG. 3B and FIG. 4A, LED elements 30 are mounted on board 10. Board 10 has a first main surface (front surface) on which LED elements 30 are mounted and a second main surface (back surface) opposite the first main surface. In the present embodiment, LED elements 30 are mounted only on the first main surface of board 10 and not on the second main surface.

As an example, when board 10 is a rectangular board, the length of board 10 in the longitudinal direction (the length of the longer side) is in a range from 93 mm to 280 mm, whereas the length of board 10 in the transverse direction (the length of the shorter side) is in a range from 10 mm to 24 mm. The thickness of board 10 is in a range from 0.8 mm to 1.2 mm, for example. Board 10 according to the present embodiment has a longer-side length of 279.4 mm, a shorter-side length of 18.4 mm, and a thickness of 1.0 mm.

### [Conductive Film]

As illustrated in FIG. 3A to FIG. 4B, conductive film 20 (conductive layer) is formed on board 10. Conductive film 20 is, for example, a metal film (metal layer) made of metal. In the present embodiment, conductive film 20 is a metal line formed in a pattern of a predetermined shape on the first main surface of board 10. Conductive film 20 is, for example, a copper line made of copper (Cu). It is to be noted that the material of conductive film 20 is not limited to copper, and a metal other than copper or a different conductive material can be used. The thickness of conductive film 20 is in a range from 15 μm to 70 μm, and is 35 μm in the present embodiment.

A current for causing LED elements 30 to emit light flows through conductive film 20. Conductive film 20 is patterned to allow the plurality of LED elements 30 on board 10 to be connected in a predetermined series-parallel connection.

Conductive film 20 having a predetermined shape can be formed by using, for example, board 10 having a metal film (copper foil, for example) fixed to the almost entire area of the first main surface in advance by pressure bonding. In this case, conductive film 20 having a predetermined shape can be patterned by partially removing a substantially-rectangular metal film by etching, for example. It is to be noted that conductive film 20 having a predetermined shape can be formed not only by patterning through etching a metal film formed on board 10 in advance, but also by printing a metal material in a predetermined shape on the first main surface of board 10.

Furthermore, conductive film 20 also has a function of releasing heat generated by LED elements 30. Therefore, conductive film 20 may be formed over a large area of the first main surface of board 10. For example, the proportion of conductive film 20 to the first main surface of board 10 (the area of conductive film 20 after being patterned/the area of the first main surface of board 10) is in a range from 50% to 78%, and is 70% in the present embodiment.

It is to be noted that a metal film (metal layer) such as copper foil may be formed also on the second main surface (back surface) of board 10. As illustrated in FIG. 4A, in the present embodiment, metal film 70 made of copper is formed on the second main surface of board 10. Forming metal film 70 on the second main surface of board 10 enables further efficient release of heat generated by LED elements 30. In this case, metal film 70 is not electrically connected with LED elements 30. In other words, metal film 70 is electrically floating, and a current for causing LED elements 30 to emit light does not passes through metal film 70. As described above, when a metal film (conductive film 20, metal film 70) is to be formed on both surfaces of board 10, it is possible to use both-surface CEM-3 board having, as the base material, board 10 on both surfaces of which a metal film such as copper foil is formed in advance.

As illustrated in FIG. 3B, conductive film 20 formed on the first main surface of board 10 includes first conductive part 21 and second conductive part 22. Each of first conductive part 21 and second conductive part 22 is formed in a predetermined shape as a part of conductive film 20.

First conductive part 21 and second conductive part 22 are separately formed. The gap (interval) between first conductive part 21 and second conductive part 22 is in a range from 0.2 mm to 0.6 mm, and is constantly 0.2 mm throughout the entire area of conductive film 20 in the present embodiment. The gap between first conductive part 21 and second conductive part 22 can be formed by, for example, etching the metal film on the first main surface of board 10 as described above. That is to say, the gap between first conductive part 21 and second conductive part 22 is a region of the metal film removed by etching. Forming this gap allows conductive film 20 to be formed in a predetermined shape.

First conductive part 21 is a part of conductive film 20 including a region which electrically connects two adjacent LED elements 30 among the plurality of LED elements 30 on board 10 and at least a portion of which is located between the two adjacent LED elements 30. In the present embodiment, first conductive part 21 is a region covered by sealing member 40, and two LED elements 30 connected by first conductive part 21 are disposed along the longitudinal direction (X-axis direction) of board 10 (a first direction).

First conductive part 21 is, for example, a region formed into an island shape between two adjacent LED elements 30. First conductive part 21 having an island shape is formed to elongate along the longitudinal direction (X-axis direction) of board 10. It is to be noted that the shape of two longitudinal end portions of elongated first conductive part 21 is, but not limited to, an arc.

As illustrated in FIG. 3B and FIG. 4A, first conductive part 21 having an island shape includes first connecting portion 21a (first bonding portion) which is a portion for connecting with one end of wire 50 (for example, wire 50a) that is a first wire connected to one of two adjacent LED elements 30 (for example, LED element 30a), and second connecting portion 21h (second bonding portion) which is a portion for connecting with one end of wire 50 (for example, wire 50b) that is a second wire connected to the other of two adjacent LED elements 30 (for example, LED element 30b).

First connecting portion 21a and second connecting portion 21b of first conductive part 21 are located between two adjacent LED elements 30 (for example, between LED element 30a and LED element 30b).

The connecting portions (first connecting portion 21a and second connecting portion 21b) of conductive film 20 (first conductive part 21) which are for connecting with wires 50 are provided as bonding pads, for example. The bonding pads can be obtained by forming resist film 60 in such a manner as to expose a part of conductive film 20 (first conductive part 21) formed in a predetermined shape on board 10, and then forming a plating layer on the exposed part of conductive film 20 (first conductive part 21).

As illustrated in FIG. 3B, a plurality of first conductive parts 21 having an island shape are formed along the longitudinal direction of board 10. Two adjacent first conductive parts 21 among the plurality of first conductive parts 21 having an island shape are formed such that one of two adjacent LED elements 30 is interposed between two adjacent first conductive parts 21. In the present embodiment, first conductive parts 21 having an island shape are located at the middle portion of board 10 in the width direction of board 10.

It is to be noted that first conductive part 21 is not limited to a region formed into a one-island shape, as long as first conductive part 21 is a part including a region which electrically connects two adjacent LED elements 30 among the plurality of LED elements 30 on board 10, and at least a portion of which is located between the two adjacent LED elements 30. For example, first conductive part 21 may be two separate regions located between two adjacent LED elements 30. In this case, the two regions of first conductive part 21 may be regions having the same potential or different potentials.

As illustrated in FIG. 3A and FIG. 3B, second conductive part 22 is a part of conductive film 20 which includes a region present on two outer sides of first conductive part 21 in a direction (a second direction) intersecting the direction in which two LED elements 30 connected by first conductive part 21 are disposed (the first direction). In the present embodiment, second conductive part 22 is a region present on two outer sides of first conductive part 21 in the Y-axis direction, with first conductive part 21 serving as a boundary. More specifically, second conductive part 22 is a region present on two outer sides of elongated sealing member 40, with sealing member 40 serving as a boundary.

At the longitudinal end portions of board 10, second conductive part 22 is a region of conductive film 20 which has a uniform potential and is physically continuous, for example. At the longitudinal end portions of board 10, second conductive part 22 having the uniform potential is formed such that first conductive part 21 having an island shape is surrounded by second conductive part 22 having the uniform potential.

It is to be noted that second conductive part 22 is not limited to a region having a uniform potential or a region which is physically continuous. For example, in a region other than the longitudinal end portions of board 10 (for example, the middle portion), second conductive part 22 on one side of sealing member 40 (the portion at the lower side of FIG. 3B) is a region which is physically continuous and having a uniform potential, whereas second conductive part 22 on the other side of sealing member 40 (the portion at the upper side of FIG. 3B) includes two regions which are physically separate and having different potentials.

With conductive film 20 having the above-described structure, second conductive part 22 has slit 22s on each of the two outer sides of first conductive part 21, and slit 22s extends in a direction intersecting the longitudinal direction of board 10. In the present embodiment, slit 22s extends in a direction orthogonal to the longitudinal direction of board 10, that is, in the Y-axis direction.

Slit 22s on one of the two outer sides of first conductive part 21 and slit 22s on the other of the two outer sides of first conductive part 21 are line-symmetric about a line connecting two adjacent LED elements 30. In the present embodiment, slit 22s is paired with opposite slit 22s such that first conductive part 21 is interposed between the pair of slits 22. As illustrated in FIG. 3A and FIG. 3B, three pairs of slits 22s are formed, for example. In other words, six slits 22s are formed.

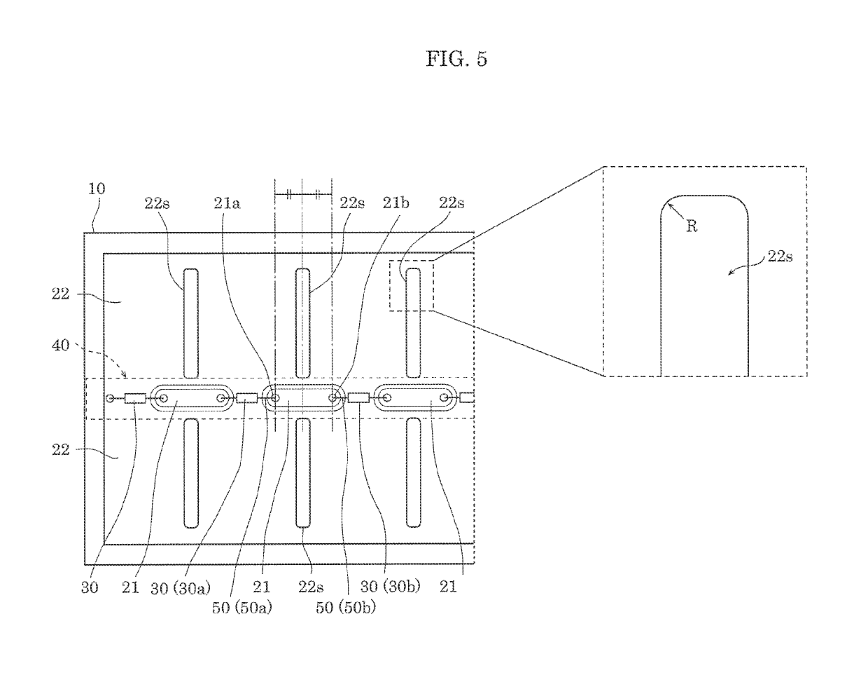

As illustrated in FIG. 5, an extension line of each slit 22s is located between (i) first connecting portion 21a of first conductive part 21 at which wire 50 (for example, wire 50a) that is the first wire is connected to first conductive part 21 and (ii) second connecting portion 21b of first conductive part 21 at which wire 50 (for example, wire 50b) that is the second wire is connected to first conductive part 21. FIG. 5 is an enlarged plan view of a longitudinal end portion of light-emitting device 1 according to the present embodiment, and is an enlarged view of the left side of FIG. 3B. As illustrated in FIG. 5, the extension line of each slit 22s in the present embodiment is located at the midpoint between first connecting portion 21a and second connecting portion 21b.

Furthermore, as illustrated in FIG. 3A and FIG. 3B, each slit 22s does not overlap sealing member 40. In other words, each slit 22s is formed not to be located below sealing member 40. In the present embodiment, each slit 22s is formed in such a manner that the farthest longitudinal edge of slit 22s matches the outer edge of sealing member 40.

Each slit 22s is surrounded by conductive film 20. In other words, the shape of slits 22s in plan view is a closed linear shape. As illustrated in FIG. 5, in plan view, each slit 22s in the present embodiment has a rectangular shape with corners having a curvature.

The length of each slit 22s (slit length) is in a range from 1.03 mm to 8.03 mm, for example, and is 5.23 mm in the present embodiment. The width of each slit 22s is in a range from 1.0 mm to 2.3 mm, for example, and is 1.5 mm in the present embodiment.

Slits 22s can be formed at the same time as first conductive part 21 and second conductive part 22, for example. For example, at the time of forming first conductive part 21 and second conductive part 22 by etching the metal film formed on board 10, slits 22s can also be formed at the same time by etching.

It is to be noted that slits 22s do not need to be formed at the same time as the patterning of first conductive part 21 and second conductive part 22, and may be formed by an etching process different from the etching process for forming first conductive part 21 and second conductive part 22. Moreover, instead of forming slits 22s by etching the metal film, it is also possible to form slits 22s by, when forming first conductive part 21 and second conductive part 22 by printing, printing first conductive part 21 and second conductive part 22 into predetermined shapes without printing the portions of slits 22s.

### [LED Elements]

As illustrated in FIG. 3B and FIG. 4A, LED elements 30 are disposed over board 10. In the present embodiment, a plurality of LED elements 30 are disposed over board 10. The plurality of LED elements 30 are disposed in a straight line along the longitudinal direction of board 10. It is to be noted that the plurality of LED elements 30 in the present embodiment are disposed in only one line. The plurality of LED elements 30 over board 10 include two adjacent LED elements 30 (for example, LED element 30a and LED element 30b).

Each LED element 30 is mounted on resist film 60 via an adhesive (not illustrated). For example, LED elements 30 are mounted on resist film 60 by die bonding using a die attach material (a die bond material). As illustrated in FIG. 4A, in the present embodiment, conductive film 20 is present below LED elements 30. In other words, LED elements 30 are mounted on resist film 60 formed on conductive film 20. In such a manner as described, conductive film 20 being present below LED elements 30 enables efficient release of heat generated by LED elements 30.

Each LED element 30 is an example of the light-emitting elements. In the present embodiment, LED elements 30 are LED chips (bare chips) which emit visible monochromatic light. For example, LED elements 30 are blue LED chips which emit blue light when current passes through LED elements 30, and are gallium nitride (GaN) semiconductor light-emitting elements having a peak wavelength in a range from 440 nm to 470 nm. Furthermore, LED elements 30 have a single-sided electrode structure in which both of a p-side electrode and an n-side electrode are formed on the top surface of a nitride semiconductor layer formed on a sapphire substrate. Each of the p-side electrode and the n-side electrode of each LED element 30 (LED chip) is wire bonded with first conductive part 21 of conductive film 20 by wire 50.

It is to be noted that although the plurality of LED elements 30 over board 10 are connected in combination of series connection and parallel connection depending on the pattern of conductive film 20, all LED elements 30 may be connected in series connection or parallel connection.

### [Sealing Member]

As illustrated in FIG. 1 to FIG. 3B, sealing member 40 seals LED elements 30 which are LED chips. In the present embodiment, sealing member 40 seals the plurality of LED elements 30 mounted on board 10. More specifically, sealing member 40 seals all LED elements 30 collectively to cover all LED elements 30 disposed in a straight line along the longitudinal direction of board 10. Sealing member 40 is thus formed in a straight line along the longitudinal direction of board 10.

Sealing member 40 is formed to extend to the two longitudinal edges of board 10. That is to say, sealing member 40 is formed continuously from the edge surface of one shorter side of board 10 to the edge surface of the opposite shorter side of board 10. It is to be noted that although sealing member 40 in the present embodiment is formed from the middle portion of one shorter side of board 10 to the middle portion of the other shorter side of board 10, sealing member 40 is not limited to this; sealing member 40 may be formed closer to one longer side of board 10.

Sealing member 40 includes (i) a wavelength converting material which is excited by light emitted by LED elements 30 to emit light having a wavelength different from the wavelength of the light emitted by LED elements 30 and (ii) a light-transmissive material containing the wavelength converting material.

An insulating resin material having a light-transmissive property, such as a silicon resin, an epoxy resin, or a fluorine based resin can be used for the light-transmissive material included in sealing member 40. The light-transmissive material is not necessarily limited to an organic material such as a resin material; an inorganic material such as glass having a low melting point or sol-gel glass may be used.

Furthermore, the wavelength converting material included in sealing member 40 is a phosphor, for example. The phosphor is contained in the light-transmissive material, and emits light of a desired color (wavelength) by emitting fluorescence when excited by, as excitation light, the light emitted from LED elements 30.

In the present embodiment, LED elements 30 are blue LED chips, and thus an yttrium aluminum garnet (YAG)-based yellow phosphor, for example, can be used as the phosphor in order to yield white light. With this, a portion of blue light emitted by the blue LED chips is absorbed and wavelength-converted to yellow light by the yellow phosphor. In other words, the yellow phosphor emits yellow light by being excited by the blue light emitted by the blue LED chips. The yellow light emitted by the yellow phosphor and blue light not absorbed by the yellow phosphor are mixed to yield white light as synthetic light, and the white light is emitted from sealing member 40.

In order to increase color rendering properties, sealing member 40 may further contain a red phosphor. Furthermore, in sealing member 40, light diffusing particles such as silica may be dispersed to increase light diffusion, or a filler, for example, may be dispersed to reduce sedimentation of the phosphor.

Sealing member 40 in the present embodiment is a phosphor containing resin formed by dispersing yellow phosphors in a silicon resin. Sealing member 40 is formed into a predetermined shape by, for example, being applied to board 10 with a dispenser so as to cover LED elements 30 mounted on board 10, and then being hardened. The cross-sectional shape of sealing member 40 formed in the above-described manner is substantially semicircle. In the present embodiment, sealing member 40 is formed in a straight line and thus has an elongated semicircular column shape.

It is to be noted that although sealing member 40 in the present embodiment is formed in a line along the array of LED elements 30, sealing member 40 is not limited to this. For example, sealing member 40 may seal each of the plurality of LED elements 30 individually. In other words, semispherical sealing member 40 may be formed for each LED element 30.

### [Wire]

LED elements 30 which are LED chips are connected to conductive film 20 of board 10 by wire bonding. More specifically, as illustrated in FIG. 3B and FIG. 4A, LED element 30 and first conductive part 21 of conductive film 20 are connected by wire 50 (bonding wire). Wire 50 is an electrical line for electrically and physically connecting LED element 30 and conductive film 20 (first conductive part 21), and is a gold wire, for example.

As illustrated in FIG. 3B and FIG. 4A, in the present embodiment, first conductive part 21 and one of two adjacent LED elements 30 (for example, LED element 30a) are connected by wire 50 (for example, wire 50a) which is a first wire extending along the longitudinal direction of board 10.

Furthermore, first conductive part 21 and the other of two adjacent LED elements 30 (for example, LED element 30b) are connected by wire 50 (for example, wire 50b) which is a second wire extending along the longitudinal direction of board 10.

Wires 50 (for example, wire 50a and wire 50c) which are the first wire and the second wire both connected to one of two adjacent LED elements 30 (for example, LED element 30a) are disposed at symmetric positions about the one of two adjacent LED elements 30 (for example, LED element 30a). In other words, two wires 50 connected to one LED element 30 are disposed at line-symmetric positions about this LED element 30 and have the same length.

A plurality of wires 50 (the first wire and the second wire) are formed along the longitudinal direction of board 10. In the present embodiment, all wires 50 sealed by sealing member 40 are disposed along the longitudinal direction of board 10, that is, along the extending direction of sealing member 40 (X-axis direction). In other words, all wires 50 connected to LED elements 30 are disposed at positions along one straight line in plan view.

It is to be noted that although each wire 50 is entirely embedded in sealing member 40, wire 50 may be partially exposed from sealing member 40.

### [Resist Film]

As illustrated in FIG. 4A and FIG. 4B, resist film 60 (resist layer) is formed above board 10. In the present embodiment, resist film 60 is formed on the first main surface side of board 10. More specifically, resist film 60 is formed on the front surface of conductive film 20 so as to cover conductive film 20 formed on the front surface of board 10.

Resist film 60 is an insulating film made of a resin material having an insulating property. Covering conductive film 20 with resist film 60 improves the insulating property (increases the dielectric strength) of board 10 and makes conductive film 20 less likely to oxidize.

Furthermore, resist film 60 in the present embodiment is made of a reflective material in order for light emitted by LED elements 30 to reflect off board 10 when the light returns to board 10. For this reason, resist film 60 is a while resist film (white resist) made of a white resin material containing a white pigment (for example, titania or silica) so as to achieve a high reflectance.

Using a white resist film for resist film 60 increases the light extraction efficiency of light-emitting device 1. It is to be noted that resist film 60 may have any one of a single-layer structure including a single layer and a laminate structure including a plurality of layers.

### [Other Structural Elements]

Although not illustrated, a pair of electrode terminals may be formed on board 10. The pair of electrode terminals are external connection terminals which receive, from the outside of light-emitting device 1, DC power for causing LED elements 30 to emit light, and are electrically connected to conductive film 20. The electrode terminals may be formed into a socket shape to which a connector line can be inserted or may be metal electrodes having a predetermined shape.

Furthermore, a protection element such as a Zener diode may be mounted on the first main surface of board 10 in order to prevent element destruction of LED elements 30 caused by reverse biasing. In addition, electric components such as a rectifier circuit element and a resistance element may be mounted on board 10.

### [Advantageous Effects]

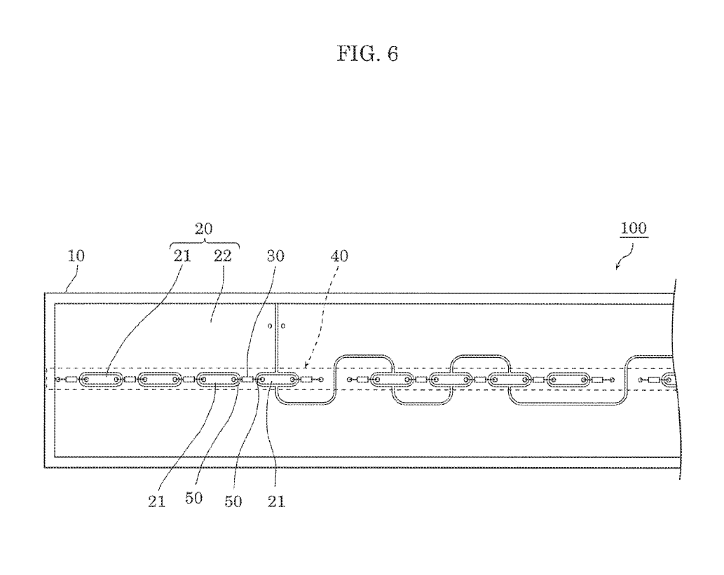

Next, advantageous effects of light-emitting device 1 according to the present embodiment will be described in comparison with light-emitting device 100 of a comparative example illustrated in FIG. 6. FIG. 6 is an enlarged plan view of light-emitting device 100 of the comparative example. It is to be noted that FIG. 6 corresponds to FIG. 3B.

The only difference between light-emitting device 100 of the comparative example illustrated in FIG. 6 and light-emitting device 1 according to the present embodiment illustrated in FIG. 3B is whether or not the light-emitting device has slits 22s. Light-emitting device 100 of the comparative example illustrated in FIG. 6 does not have slits 22s that light-emitting device 1 according to the present embodiment illustrated in FIG. 3B has. It is to be noted that resist film 60 is omitted also in FIG. 6.

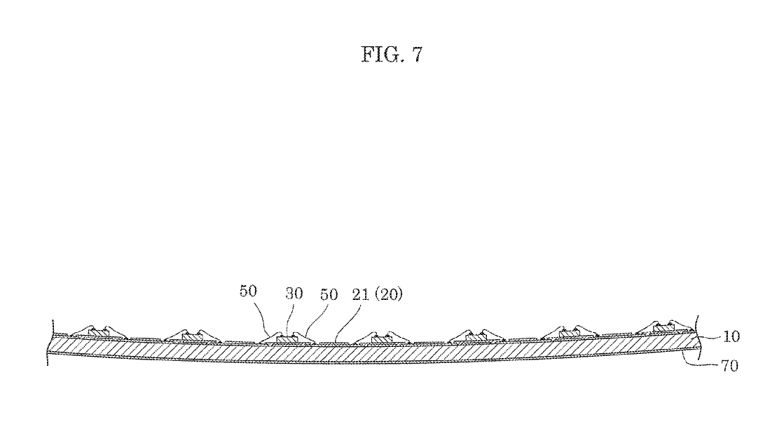

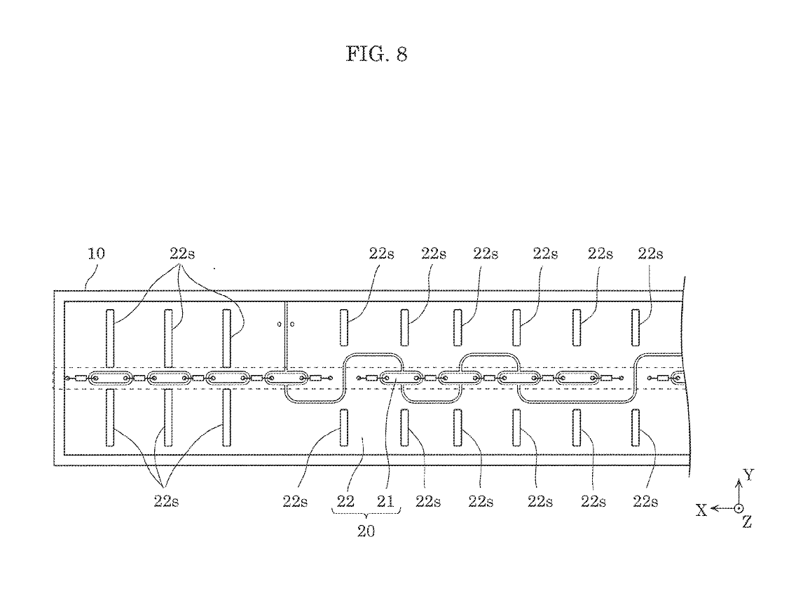

With light-emitting device 100 of the comparative example illustrated in FIG. 6, because light-emitting device 100 (board 10) has an elongated shape as a whole, board 10 warps, causing light-emitting device 100 to be bent as a whole. For example, light-emitting device 100 suffers from a recessed warp as illustrated in FIG. 7.

Warping of board 10 places a load on a portion connecting LED element 30 and conductive film 20, which may result in faulty electrical continuity (no illumination). More specifically, when board 10 warps, strain stress caused by the warping of board 10 places a load on the portion of conductive film 20 (first conductive part 21) for connecting with wire 50, which may result in breakage of wire 50 that causes faulty electrical continuity.

In view of this, as illustrated in FIG. 3A and FIG. 3B, with light-emitting device 1 according to the present embodiment, second conductive part 22 has slit 22s on each of two outer sides of first conductive part 21, and slit 22s extends in a direction intersecting the longitudinal direction of board 10.

This allows the strain stress caused by the warping of board 10 to be dispersed in a balanced manner by slits 22s formed on the two outer sides of first conductive part 21. That is to say, slits 22s can absorb and alleviate the strain stress caused by distortion of board 10. It is thus possible to reduce the load on the portion of conductive film 20 (first conductive part 21) for connecting with wire 50, and is therefore possible to reduce the occurrence of faulty electrical continuity caused by breakage of wire 50.

With light-emitting device 1 according to the present embodiment, since slits 22s are formed in second conductive part 22 of conductive film 20, it is possible to reduce the occurrence of faulty electrical continuity caused by wire breakage attributable to the warping of board 10.

Furthermore, in the present embodiment, the first direction is the longitudinal direction of board 10.

In the case where the plurality of LED elements 30 are disposed along the longitudinal direction of board 10, the load on the portion of conductive film 20 (first conductive part 21) for connecting with wire 50 increases due to the strain stress caused by the warping of board 10 and thus breakage of wire 50 easily occurs, as compared to the case where the plurality of LED elements 30 are disposed along the transverse direction of board 10.

Thus, in the case where the plurality of LED elements 30 are disposed along the longitudinal direction of board 10, forming slits 22s along the direction intersecting the longitudinal direction of board 10 effectively reduces the occurrence of faulty electrical continuity caused by wire breakage attributable to the warping of board 10.

In the present embodiment, each of LED elements 30 is an LED chip. First conductive part 21 and one of two adjacent LED elements 30 are connected by wire 50 which is a first wire extending along the longitudinal direction of board 10, the first wire being connected to first conductive part 21 at first connecting portion 21a of first conductive part 21. First conductive part 21 and the other of two adjacent LED elements 30 are connected by wire 50 which is a second wire extending along the longitudinal direction of board 10, the second wire being connected to first conductive part 21 at second connecting portion 21b of first conductive part 21. Furthermore, an extension line of slit 22s is located between first connecting portion 21a and second connecting portion 21b. That is to say, slit 22s is formed between first connecting portion 21a and second connecting portion 21b (between two adjacent wires 50).

With this, the strain stress of board 10 caused by the warping of board 10 can be concentrated between first connecting portion 21a and second connecting portion 21b. As a result, it is possible to reduce the stress on first connecting portion 21a and second connecting portion 21b. It is therefore possible to further reduce the occurrence of the faulty electrical continuity caused by wire breakage attributable to the warping of board 10.

In this case, two wires 50 which are connected to one of two adjacent LED elements 30 may be disposed at symmetric positions about this LED element 30.

This makes it possible to impart the strain stress of board 10 equally to the two connecting portions of one first conductive part 21, that is, first connecting portion 21a and second connecting portion 21b. It is therefore possible to further reduce the occurrence of the faulty electrical continuity caused by wire breakage attributable to the warping of board 10.

Furthermore, in the present embodiment, first connecting portion 21a and second connecting portion 21b are located between two adjacent LED elements 30 disposed along the longitudinal direction of board 10.

In this case, the load placed on first connecting portion 21a and second connecting portion 21b easily increases due to the strain stress caused by the warping of board 10, and thus the breakage of wire 50 easily occurs.

Therefore, in the case where first connecting portion 21a and second connecting portion 21b are located between two adjacent LED elements 30, forming slits 22s along the direction intersecting the longitudinal direction of board 10 effectively reduces the occurrence of the faulty electrical continuity caused by wire breakage attributable to the warping of board 10.

Furthermore, in the present embodiment, the extension line of slit 22s is located at the midpoint between first connecting portion 21a and second connecting portion 21b.

With this, slits 22s can equally reduce the load placed on first connecting portion 21a and second connecting portion 21b due to the strain stress of board 10. It is therefore possible to further reduce the occurrence of the faulty electrical continuity caused by wire breakage attributable to the warping of board 10.

Furthermore, in the present embodiment, the plurality of LED elements 30 are sealed by sealing member 40.

With this, the plurality of LED elements 30 can be protected by sealing member 40. Moreover, containing a phosphor in sealing member 40 enables emission of light of a desired color through synthetic light of light from LED elements 30 and fluorescence from the phosphor.

Furthermore, in the present embodiment, slit 22s does not overlap sealing member 40. More specifically, slit 22 is located outside sealing member 40 so as not to overlap sealing member 40.

This reduces the impact that slits 22s have on sealing member 40. For example, overlap of slits 22s and sealing member 40 leads to an increase in the thickness of sealing member 40 in the overlapped portion, which may hinder desired light distribution. Furthermore, if sealing member 40 has a portion where slits 22s are present and a portion where slits 22s are absent, color irregularities may occur due to a variation in the amount of phosphor between these portions.

Furthermore, in the present embodiment, slit 22s on one of the two outer sides of first conductive part 21 and slit 22s on the other of the two outer sides of first conductive part 21 are line-symmetric about a line connecting two adjacent LED elements 30.

With this, a pair of slits 22s can further equally reduce the load placed on first connecting portion 21a and second connecting portion 21b due to the strain stress of board 10. It is therefore possible to further effectively reduce the occurrence of the faulty electrical continuity caused by wire breakage attributable to the warping of board 10.

Furthermore, in the present embodiment, slit 22s is surrounded by conductive film 20.

With this, slit 22s can efficiently absorb the load placed on first connecting portion 21a and second connecting portion 21b due to the strain stress of board 10.

Furthermore, in the present embodiment, in plan view, slit 22s has a rectangular shape with corners having a curvature.

This reduces the occurrence of, for example, a crack in conductive film 20 (second conductive part 22) caused by slits 22s absorbing the strain stress of board 10.

### [Variations]

Although the light-emitting device according to the present disclosure has been described above based on an embodiment, the present disclosure is not limited to the embodiment described above.

For example, although the above-described embodiment has illustrated that slits 22s are formed only at the longitudinal end portions of board 10, slits 22s are not limited to this and may be formed throughout the entire longitudinal area of board 10 as illustrated in FIG. 8.

As described above, forming slits 22s throughout the entire longitudinal area of board 10 enables further even distribution of the strain stress of board 10 caused by the warping of board 10. With this, it is possible to further reduce the occurrence of the faulty electrical continuity caused by wire breakage attributable to the warping of board 10.

However, when light-emitting device 100 (board 10) has a recessed warp as illustrated in FIG. 7, slits 22 formed at the longitudinal end portions of board 10 largely contribute to the reduction of the strain stress of board 10, as compared to slits 22s formed at the longitudinal middle portion of board 10. Therefore, a greater slit width may be given to slits 22s formed at the longitudinal end portions of board 10.

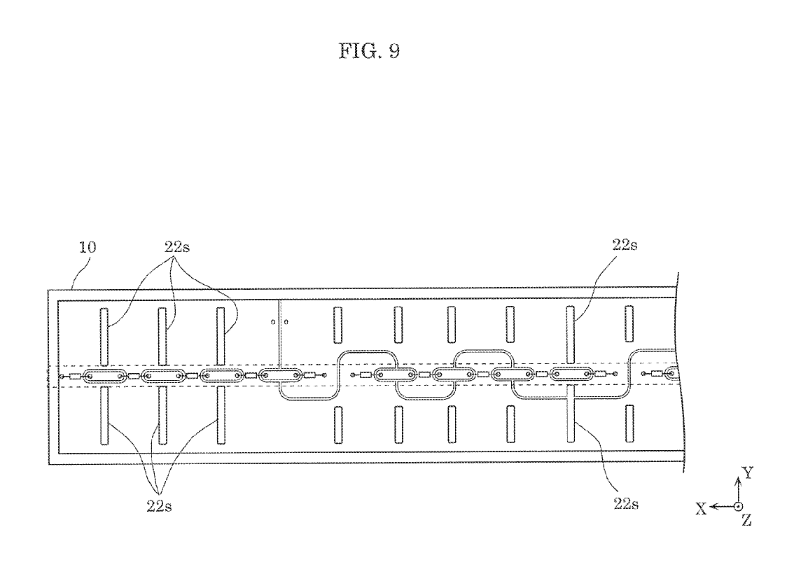

Furthermore, since longer slits 22s are more capable of alleviating the strain stress of board 10 caused by the warping of board 10, slits 22s may be formed across regions of conductive film 20 which have different potentials as illustrated in FIG. 9.

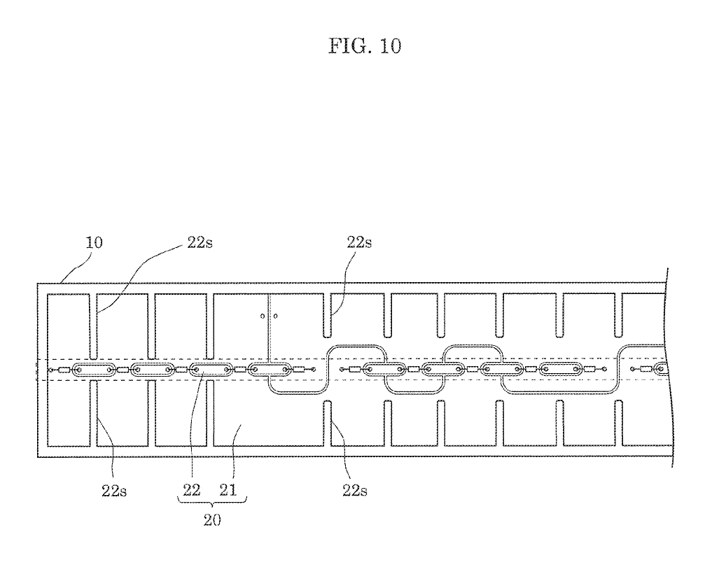

Although slits 22s in the above embodiment are surrounded by conductive film 20, slits 22s are not limited to this. For example, slits 22s may be notches as illustrated in FIG. 10. More specifically, slits 22s may be formed as notches extending inwardly of board 10 from the outer edge of conductive film 20 (second conductive part 22).

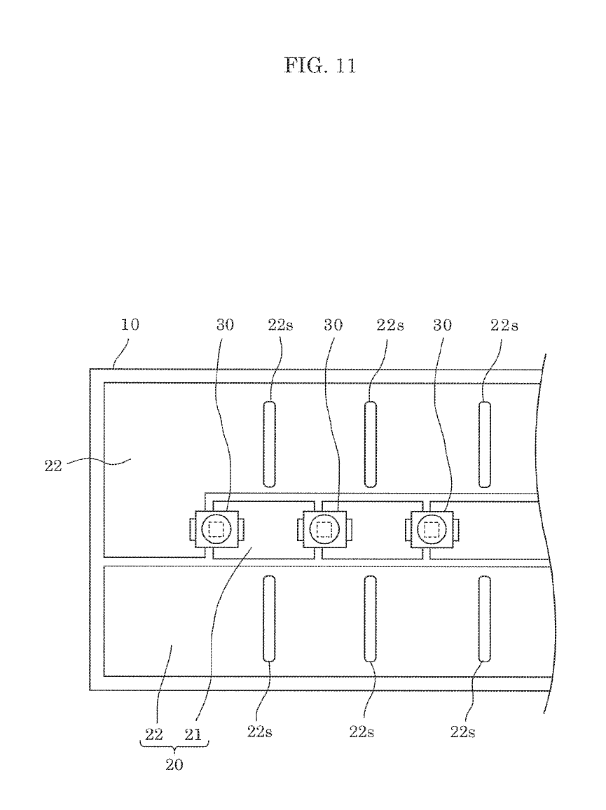

Furthermore, although the above embodiment has illustrated a COB light-emitting device in which LED elements 30 are mounted directly on board 10 as LED chips, the present disclosure is not limited to this. For example, as illustrated in FIG. 11, the light-emitting device may be configured by mounting one or a plurality of LED elements 30 on board 10, using, as LED elements 30, SMD LED elements in which LED chips are individually packaged. In this case, SMD LED elements 30 each include, for example, (i) a container made from a white resin and having a recessed portion, (ii) an LED chip (for example, a blue LED chip) mounted in the recessed portion of the container, and (iii) a sealing member (for example, a yellow-phosphor containing resin) sealed in the recessed portion of the container.

Furthermore, although, in the above embodiment, only one slit 22s is formed between first connecting portion 21a and second connecting portion 21b of first conductive part 21, slits 22s are not limited to this configuration; two or more slits 22s may be formed between first connecting portion 21a and second connecting portion 21b.

Moreover, although resist film 60 is formed in the above embodiment, resist film 60 does not necessarily need to be formed.

In addition, although the above embodiment has illustrated that white light is emitted using a blue LED chip and a yellow phosphor, white light is not limited to this combination. For example, white light may be emitted using a phosphor containing resin which contains a red phosphor and a green phosphor and combining this phosphor containing resin with a blue LED chip. An LED chip which emits light of a color other than blue may be used. Alternatively, white light may be generated by combining (i) an ultraviolet LED chip which emits ultraviolet light having a wavelength shorter than the wavelength of light a blue LED chip emits and (ii) phosphors of different colors, each of which emits light of one of three primary colors (red, green, or blue) by being excited mainly by ultraviolet light.

Moreover, although a phosphor is used as the wavelength converting material in the above embodiment, the wavelength converting material is not limited to this. For example, it is possible to use, as the wavelength converting material, a material containing a substance which absorbs light having a certain wavelength and emits light having a wavelength different from the wavelength of the absorbed light, such as a semiconductor, a metal complex, an organic dye, or a pigment.

Furthermore, although light-emitting device 1 in the above embodiment emits white light, light-emitting device 1 is not limited to this. For example, light-emitting device 1 may emit monochromatic light such as blue light or emit light of a different color.

The light-emitting device in the above embodiment can be used as an illumination light source in a lighting fixture (lighting apparatus) such as a downlight, a spotlight, or a base light. Other than that, the light-emitting device according to the above embodiment and variations may be used as a backlight light source in, for example, a liquid crystal display apparatus, a lamp light source in, for example, a copying machine, a light source in, for example, a guide light or a signboard apparatus, or a light source for a purpose other than illumination.

Although only an exemplary embodiment of the present disclosure and variations thereof have been described in detail above, those skilled in the art will readily appreciate that many modifications are possible in the exemplary embodiment and variations without materially departing from the novel teachings and advantages of the present disclosure. Accordingly, all such modifications are intended to be included within the scope of the present disclosure.

What is claimed is:

1. A light-emitting device comprising:
a board which is a resin board having an elongated shape;
a conductive film formed on the board; and
a plurality of light-emitting elements disposed over the board,
wherein the plurality of light-emitting elements include two adjacent light-emitting elements arranged along a first direction,
the conductive film includes (i) a first conductive part which electrically connects the two adjacent light-emitting elements and at least a portion of which is located between the two adjacent light-emitting elements and (ii) a second conductive part located on two outer sides of the first conductive part in a second direction intersecting the first direction, and
the second conductive part has a slit on each of the two outer sides of the first conductive part, the slit extending in the second direction intersecting a longitudinal direction of the board.

2. The light-emitting device according to claim 1,
wherein the first direction is the longitudinal direction of the board.

3. The light-emitting device according to claim 2,
wherein each of the plurality of light-emitting elements is a light-emitting diode (LED) chip,
the first conductive part and one of the two adjacent light-emitting elements are connected by a first wire extending along the longitudinal direction of the board, the first wire being connected to the first conductive part at a first connecting portion of the first conductive part,
the first conductive part and the other of the two adjacent light-emitting elements are connected by a second wire extending along the longitudinal direction of the board, the second wire being connected to the first conductive part at a second connecting portion of the first conductive part, and
an extension line of the slit is located between the first connecting portion and the second connecting portion.

4. The light-emitting device according to claim 3,
wherein a plurality of first conductive parts each being the first conductive part, a plurality of first wires each being the first wire, and a plurality of second wires each being the second wire are formed along the longitudinal direction of the board,
two adjacent first conductive parts among the plurality of first conductive parts are formed such that one of the two adjacent light-emitting elements is interposed between the two adjacent first conductive parts, and
the first wire and the second wire which are connected to one of the two adjacent light-emitting elements are disposed at symmetric positions about the one of the two adjacent light-emitting elements.

5. The light-emitting device according to claim 3,
wherein the first connecting portion and the second connecting portion are located between the two adjacent light-emitting elements.

6. The light-emitting device according to claim 3,
wherein the extension line of the slit is located at a midpoint between the first connecting portion and the second connecting portion.

7. The light-emitting device according to claim 1, further comprising
a sealing member which seals the plurality of light-emitting elements.

8. The light-emitting device according to claim 7,
wherein the slit does not overlap the sealing member.

9. The light-emitting device according to claim 1,
wherein the slit on one of the two outer sides of the first conductive part and the slit on the other of the two outer sides of the first conductive part are line-symmetric about a line connecting the two adjacent light-emitting elements.

10. The light-emitting device according to claim 1,
wherein the slit is surrounded by the conductive film.

11. The light-emitting device according to claim 10,
wherein, in plan view, the slit has a rectangular shape with corners having a curvature.

12. A light-emitting device comprising:
a board having a longer side extending in a first direction and a shorter side shorter than the longer side and extending in a second direction perpendicular to the first direction;
a conductive film formed on the board; and
a plurality of light-emitting elements disposed over the board,
wherein the plurality of light-emitting elements include two adjacent light-emitting elements arranged along the first direction,
the conductive film includes (i) a first conductive part which electrically connects the two adjacent light-emitting elements and at least a portion of which is located between the two adjacent light-emitting elements and (ii) a second conductive part including a first region and a second region,
the first region and the second region are located on two outer sides of the first conductive part in the second direction, and
the first region includes a first slit and the second region includes a second slit, the first and second slits extending in the second direction.

13. The light-emitting device according to claim 12,
wherein each of the plurality of light-emitting elements is a light-emitting diode (LED) chip.

14. The light-emitting device according to claim 12,
wherein the first conductive part and one of the two adjacent light-emitting elements are connected by a first wire extending along the longitudinal direction of the board, the first wire being connected to the first conductive part at a first connecting portion of the first conductive part,
the first conductive part and the other of the two adjacent light-emitting elements are connected by a second wire extending along the longitudinal direction of the board, the second wire being connected to the first conductive part at a second connecting portion of the first conductive part, and
a line connecting the first and second slits is located between the first connecting portion and the second connecting portion.

15. The light-emitting device according to claim 14,
wherein a plurality of first conductive parts each being the first conductive part, a plurality of first wires each being the first wire, and a plurality of second wires each being the second wire are formed along the longitudinal direction of the board,
two adjacent first conductive parts among the plurality of first conductive parts are formed such that one of the two adjacent light-emitting elements is interposed between the two adjacent first conductive parts, and
the first wire and the second wire which are connected to one of the two adjacent light-emitting elements are disposed at symmetric positions about the one of the two adjacent light-emitting elements.

16. The light-emitting device according to claim 15,
wherein a plurality of first slits each being the first slit are formed in the first region and a plurality of second slits each being the second slit are formed in the second region.

17. The light-emitting device according to claim 14,
wherein the line connecting the first and second slits intersects the line connecting the first connecting portion and the second connecting portion at a midpoint of a line connecting the first connecting portion and the second connecting portion.

18. The light-emitting device according to claim 12, further comprising
a sealing member which seals the plurality of light-emitting elements.

19. The light-emitting device according to claim 18,
wherein the first and second slits do not overlap the sealing member.
